(19) United States
(12) Patent Application Publication
(10) Pub. No.: US 2007/0176170 A1
(43) Pub. Date: Aug. 2, 2007

(54) Organic light-emitting device with integrated color filter and method for manufacturing the same

(75) Inventors: King-Yuan Ho, Chiayi County (TW); Po-Chu Chen, Hsinchu City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/480,888

(22) Filed: Jul. 6, 2006

(30) Foreign Application Priority Data
Jan. 27, 2006 (TW) 095103346

(51) Int. Cl. H01L 51/40; H01L 29/08; H01L 35/24; H01L 51/00; H01L 33/00; H01L 29/22; H01L 29/227

(52) U.S. Cl. 257/40; 257/98

(57) ABSTRACT

The present invention relates to an organic light-emitting device with an integrated color filter and a method for manufacturing the same. The organic light-emitting device is manufactured with a metal layer depositing process for raising the source/drain layer so that the sidewall area of a pixel electrode formed in a contact hole is reduced and thus the contact resistance of the pixel electrode is decreased for reducing power loss. Moreover, since the sidewall of the contact hole formed by the method of the invention is not overly abrupt, the breaking or cracking of the portion of the pixel electrode formed in the contact hole can be prevented.

### BACKGROUND OF THE INVENTION

1. Field of the Invention

The present invention generally relates to an organic light-emitting device with an integrated color filter and a method for manufacturing the same and, more particularly, to an organic light-emitting device and a method for manufacturing the organic light-emitting device having a reduced sidewall area of a pixel electrode formed in a contact hole and thus a decreased contact resistance of the pixel electrode.

2. Description of the Prior Art

Conventionally, white-light organic light-emitting diodes (OLEDs) use a color filter layer so as to implement full color display, in which the color filter layer is combined with a glass substrate on which is formed a array circuit comprising a plurality of thin-film transistors (TFTs). Alignment issue occurs due to uncontrollable processing that results in poor color purity.

The state-of-the-art integrated color filter (ICF) uses a color photo-resist layer spin-coated on the TFT array so as to enhance color purity and simply the process. However, the coated color filter layer thickens the panel and increases the area of the pixel electrode so that the increased contact resistance leads to larger power consumption and, thus, lower luminous efficiency.

Please refer to FIG. 1, which is a schematic cross-sectional view of a conventional organic light-emitting device. The method for manufacturing the organic light-emitting device comprises steps of: defining a patterned poly-silicon layer 11 on a substrate 10; forming a gate insulating layer 12 and a gate layer 13 as a mask for ion implantation so as to form source/drain diffusion regions 11a, 11b and a channel region 11c; depositing an insulating layer 14 with contact holes so as to expose the source/drain diffusion regions 11a, 11b; depositing a metal layer filling the contact holes; patterning the metal layer as source/drain electrodes 15a, 15b; spin-coating a color photo-resist layer and defining the color photo-resist layer as a color filter layer 16; depositing an organic material layer and planarizing the organic material layer by spin-coating as a planarization layer 17 exposing the source/drain electrode, 15b; and depositing a transparent conductive layer 18 comprising indium-tin oxide (ITO) as the anode of the pixel electrode.

In the afore-mentioned prior art, the panel is thickened due to the additional color filter 16 so that the depth h1 of the transparent conductive layer 18 is increased. The sidewall area of the transparent conductive layer 18 is increased so as to enhance the contact resistance that leads to larger power consumption on the junction instead of the organic light-emitting diode. On the other hand, the abrupt profile of the transparent conductive layer 18 also leads to breaking or cracking of the portion of the pixel electrode.

Therefore, there exists a need in providing an organic light-emitting device with an integrated color filter and a method for manufacturing the same so as to reduce the contact resistance and enhance the brightness of the device.

### SUMMARY OF THE INVENTION

It is a primary object of the present invention to provide an organic light-emitting device with an integrated color filter and a method for manufacturing the same so as to reduce the contact resistance and enhance the brightness of the device.

It is a secondary object of the present invention to provide an organic light-emitting device with an integrated color filter and a method for manufacturing the same so as to prevent the breaking or cracking of the portion of a pixel electrode formed in the contact hole due to the elevation of the height to the source/drain layer.

It is another object of the present invention to provide an organic light-emitting device with an integrated color filter and a method for manufacturing the same so as to reduce the contact resistance and prevent the breaking or cracking of the portion of a pixel electrode formed in the contact hole with only one additional photo-lithographic process.

In order to achieve the foregoing objects, the present invention provides an organic light-emitting device, comprising: a substrate; a transistor formed on the substrate; a source/drain metal layer coupled to the transistor; a metal layer formed on the source/drain metal layer; a color filter layer formed on the transistor and exposing the metal layer; a planarization layer formed on the color filter layer and exposing the metal layer; and a transparent conductive layer formed on the planarization layer and coupled to the metal layer.

In a first embodiment, the transistor has a top gate. The top-gate transistor comprises: a poly-silicon layer formed on the substrate and comprising a channel region and source/drain diffusion regions; a gate insulating layer formed on the substrate and covering the poly-silicon layer; a gate layer formed on the gate insulating layer; an insulating layer formed on the gate layer and the gate insulating layer; and contact holes penetrating the insulating layer and the gate insulating layer so as to expose the source/drain diffusion regions.

In a second embodiment, the transistor has a top gate. The bottom-gate transistor comprises: a gate layer formed on the substrate; a gate insulating layer formed on the substrate and covering the gate layer; an amorphous silicon layer formed on the gate insulating layer and comprising a channel region; and a heavily doped amorphous silicon layer formed on two sides of the amorphous silicon layer.

Preferably, the metal layer and the source/drain metal layer are formed of the same material. Preferably, the substrate is a glass substrate. Preferably, the planarization layer is an organic material layer. Preferably, the transparent conductive layer is an indium-tin oxide (ITO) layer. Preferably, the gate insulating layer is a silicon oxide layer. Preferably, the insulating layer is a silicon oxide layer.

In order to achieve the foregoing objects, the present invention provides a method for manufacturing an organic light-emitting device, comprising steps of: providing a substrate; forming a transistor on the substrate; forming a source/drain metal layer coupled to the transistor; forming a metal layer on the source/drain metal layer; forming a color filter layer on the transistor and the color filter layer exposing the metal layer; forming a planarization layer on the color filter layer and the planarization layer exposing the metal layer; and forming a transparent conductive layer on the planarization layer and the transparent conductive layer being coupled to the metal layer.

In a first embodiment, the transistor has a top gate. The steps for manufacturing the transistor comprise: forming a poly-silicon layer on the substrate; forming a gate insulating layer on the substrate and the gate insulating layer covering the poly-silicon layer; forming a gate layer on the gate insulating layer; performing a ion-implantation process so as to form source/drain diffusion regions in the poly-silicon layer; forming an Insulating layer on the gate layer and the gate insulating layer; and forming contact holes penetrating the insulating layer and the gate insulating layer so as to expose the source/drain diffusion regions.

In a second embodiment, the transistor has a top gate. The steps for manufacturing the transistor comprise: forming a gate layer on the substrate; forming a gate insulating layer on the substrate and the gate insulating layer covering the gate layer; forming an amorphous silicon layer on the gate insulating layer and the amorphous silicon layer comprising a channel region; and forming a heavily doped amorphous silicon layer on two sides of the amorphous silicon layer.

Preferably, method for manufacturing an organic light-emitting device, comprising a step of: forming a photo-resist layer on the metal layer. Preferably, method for manufacturing an organic light-emitting device, comprising a step of: performing a dry-etching process so as to remove the part of the metal layer uncovered by the photo-resist layer. Preferably, method for manufacturing an organic light-emitting device, comprising a step of: performing a lift-off process so as to remove the photo-resist layer.

Preferably, the metal layer and the source/drain metal layer are formed of the same material. Preferably, the substrate is a glass substrate. Preferably, the planarization layer is an organic material layer. Preferably, the transparent conductive layer is an indium-tin oxide (ITO) layer. Preferably, the gate insulating layer is a silicon oxide layer. Preferably, the insulating layer is a silicon oxide layer.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a schematic cross-sectional view of a conventional organic light-emitting device;

FIG. 2 to FIG. 13 are cross-sectional views showing a method for manufacturing an organic light-emitting device according to a first embodiment of the present invention; and

FIG. 14 to FIG. 19 are cross-sectional views showing a method for manufacturing an organic light-emitting device according to a second embodiment of the present invention.

### DETAILED DESCRIPTION OF THE PREFERRED EMBODIMENT

The present invention providing an organic light-emitting device with an integrated color filter and a method for manufacturing the same can be exemplified by the preferred embodiments as described hereinafter.

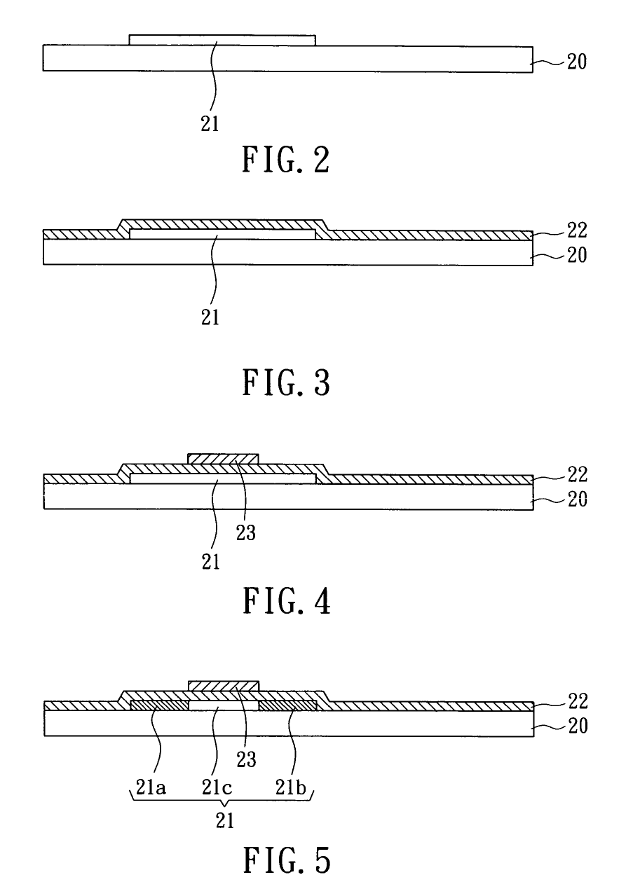

Please refer to FIG. 2 to FIG. 13, which are cross-sectional views showing a method for manufacturing an organic light-emitting device according to a first embodiment of the present invention. The present invention discloses an organic light-emitting device with an integrated color filter and a method for manufacturing the organic light-emitting device. In the first embodiment, the method comprises steps described hereinafter:

As shown in FIG. 2, a patterned poly-silicon layer 21 is formed on a pre-determined portion of a substrate 20.

Then, in FIG. 3, a gate insulating layer 22 is deposited so as to cover the substrate 20 and the patterned poly-silicon layer 21.

In FIG. 4, a patterned gate layer 23 is formed on the patterned poly-silicon layer 21.

As shown in FIG. 5, the gate layer 23 is used as a mask for ion implantation so as to form source/drain diffusion regions 21a, 21b in the poly-silicon layer 21 on two sides of the gate layer 23. Meanwhile, the un-doped region of the poly-silicon layer 21 under the gate layer 23 is a channel region 21c.

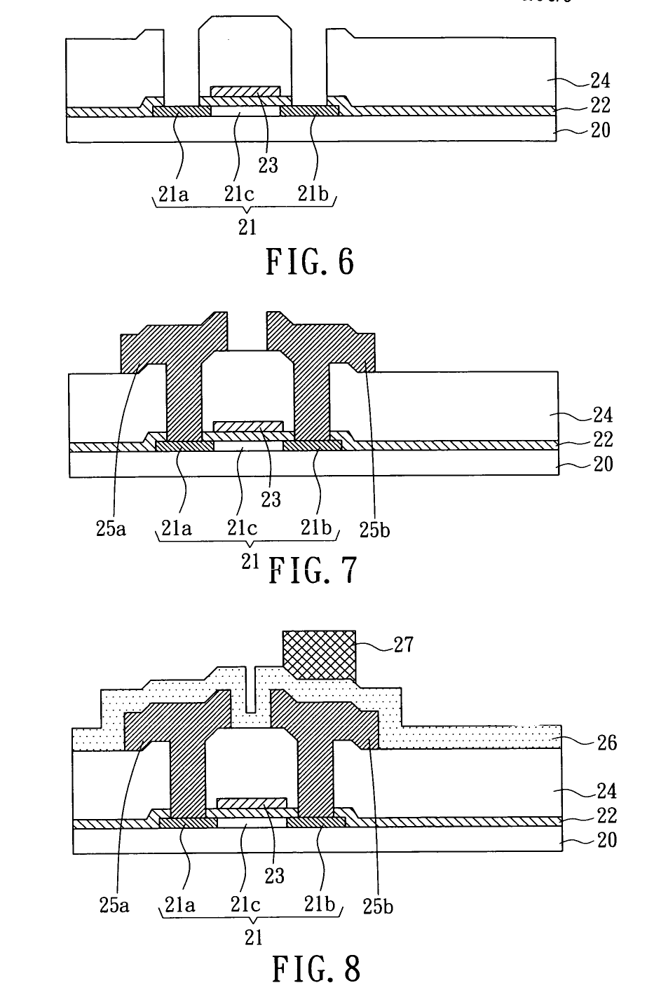

In FIG. 6, an insulating layer 24 is deposited so as to cover the gate insulating layer 22 and the gate layer 23, and photo-lithography is used to form contact holes in the insulating layer 24 so as to expose the source/drain diffusion regions 21a, 21b. A transistor is thus completed.

As shown in FIG. 7, a metal layer (not shown) is deposited on the insulating layer 24 so as to fill the contact holes and define the metal layer as the source/drain 25a, 25b. The thickness of the source/drain metal layer used as conducting wires is larger than that of general metal wires so as to prevent over etching the metal layer for the source/drain 25a, 25b.

In FIG. 8, an additional metal layer 26 is deposited so as to cover the insulating layer 24 and the source/drain 25a, 25b. Furthermore, a patterned photo-resist layer 27 is formed using photo-lithography on a pre-determined area on the metal layer 26, for example, over the source/drain 25b.

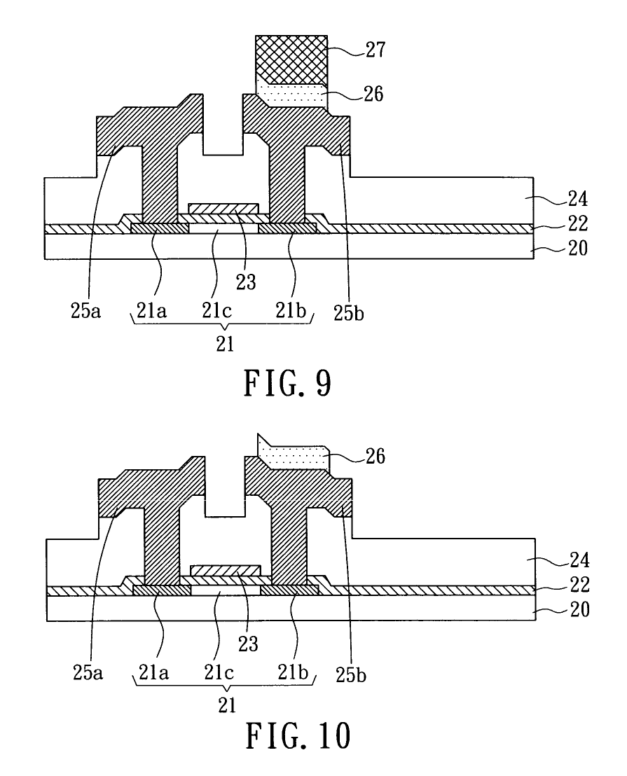

In FIG. 9, an anisotropic dry-etching process is performed so as to control the etching profile of the sidewall. Over-etching is done so as to assure that no residual metal is left on the insulating layer 24. The insulating layer 24 is thinned due to over-etching so that the thickness of the insulating layer 24 in FIG. 9 is smaller than that of the insulating layer 24 in FIG. 8. Furthermore, the thickness of the metal layer for the source/drain 25a is reduced due to over-etching. Since the thickness of the source/drain metal layer (in FIG. 7) is larger than that of general metal wires, the over-etched metal layer for the source/drain 25a, 25b will not be over-etched too thin.

In FIG. 10, the photo-resist layer 27 is removed.

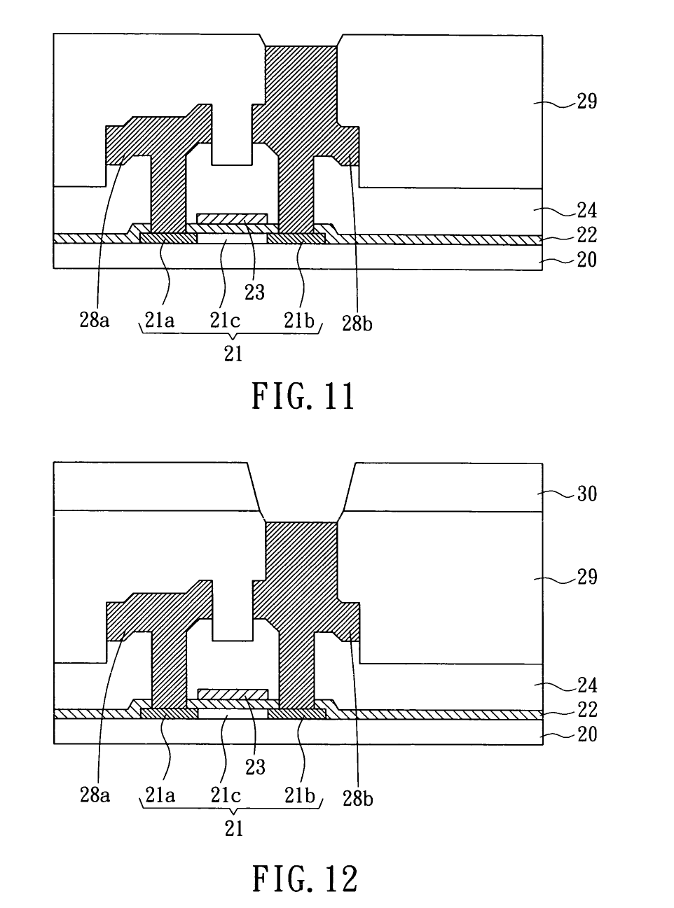

Referring to FIG. 11, the metal layer 26 and the metal layer for the source/drain 25a, 25b use the same metal material and, therefore, the metal layer 26 serves as a new metal layer for the source/drain 28b. It is obvious that the metal layer for the source/drain 28b is thicker than the metal layer for the source/drain 25b. Then, a color photo-resist is defined as a color filter layer 29 so as to expose the metal layer for the source/drain 28b. Since the thickness of the insulating layer 24 is reduced, the color filter layer 29 can be disposed lowered.

In FIG. 12, an organic material layer is deposited and is planarized by spin-coating to form a planarization layer 30. The metal layer for the source/drain 28b is exposed. The organic material layer can be PC 403 positive photo-resist. Similarly, since the thickness of the insulating layer 24 is reduced, the planarization layer 30 can be disposed lowered.

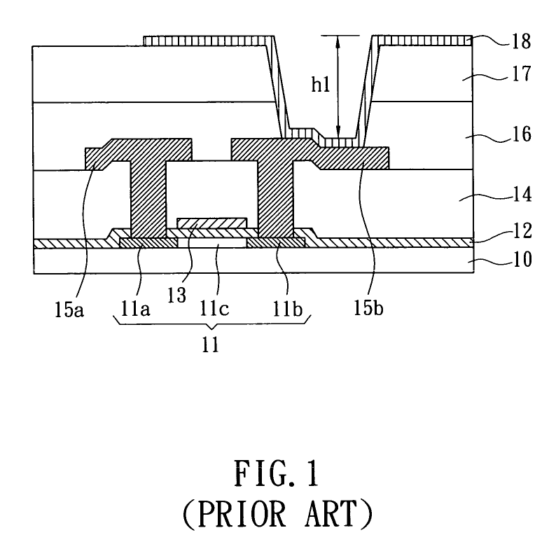

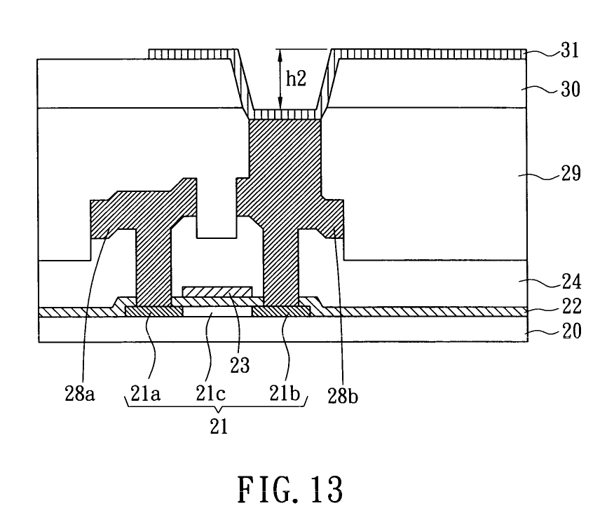

As shown in FIG. 13, a transparent conductive layer 31 formed of indium-tin oxide (ITO) is deposited as the anode of the pixel electrode. Since the metal layer for the source/drain 28b is thicker than the metal layer for the source/drain 25b and the planarization layer 30 is disposed lowered, the depth h2 of the transparent conductive layer 31 is smaller than h1 in FIG. 1. Therefore, the sidewall area of the transparent conductive layer 31 as well as the contact resistance is significantly reduced. Furthermore, the profile of the transparent conductive layer 31 is not overly abrupt so that the breaking or cracking of the portion of the pixel electrode can be prevented.

Afterwards, an organic light-emitting layer (not shown) and a cathode layer (not shown) are deposited so as to complete an active matrix organic light-emitting display (AMOLED).

In the first embodiment, the substrate 20 is a glass substrate. The gate insulating layer 22 is a silicon oxide layer. The insulating layer 24 is a silicon oxide layer. The thickness of the additional metal layer 26 can be arbitrarily determined. Due to the additional metal layer 26, the sidewall area of the transparent conductive layer 31 as well as the contact resistance is significantly reduced. Preferably, the channel of the transistor in the present embodiment can be p-channel or n-channel.

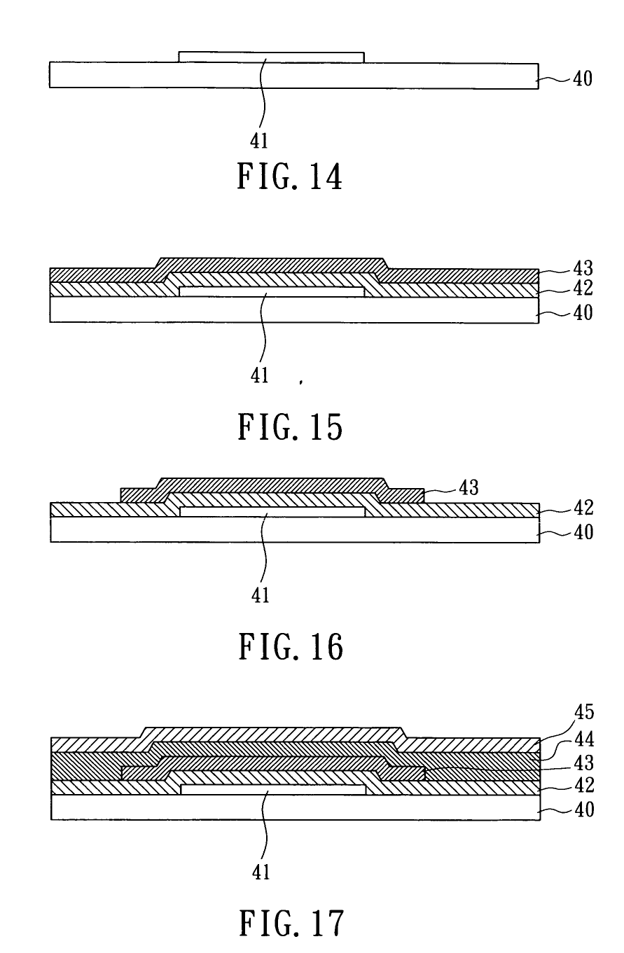

FIG. 14 to FIG. 19 are cross-sectional views showing a method for manufacturing an organic light-emitting device according to a second embodiment of the present invention. The present invention discloses an organic light-emitting device with an integrated color filter and a method for manufacturing the organic light-emitting device. In the second embodiment, the method comprises steps described hereinafter:

As shown in FIG. 14, a patterned gate layer 41 is formed on a pre-determined portion of a substrate 40.

In FIG. 15, a gate insulating layer 42 is deposited so as to cover the substrate 40 and the patterned gate layer 41. Then, an amorphous silicon layer 43 is formed on the gate insulating layer 42.

In FIG. 16, photo-lithography and etching are used to remove a portion of the amorphous silicon layer 43 while remaining the portion of amorphous silicon layer 43 on the gate layer 41.

As shown in FIG. 17, a heavily doped amorphous silicon layer 44 is formed on the amorphous silicon layer 43 and the gate insulating layer 42. Furthermore, a metal layer 45 is formed on the heavily doped amorphous silicon layer 44.

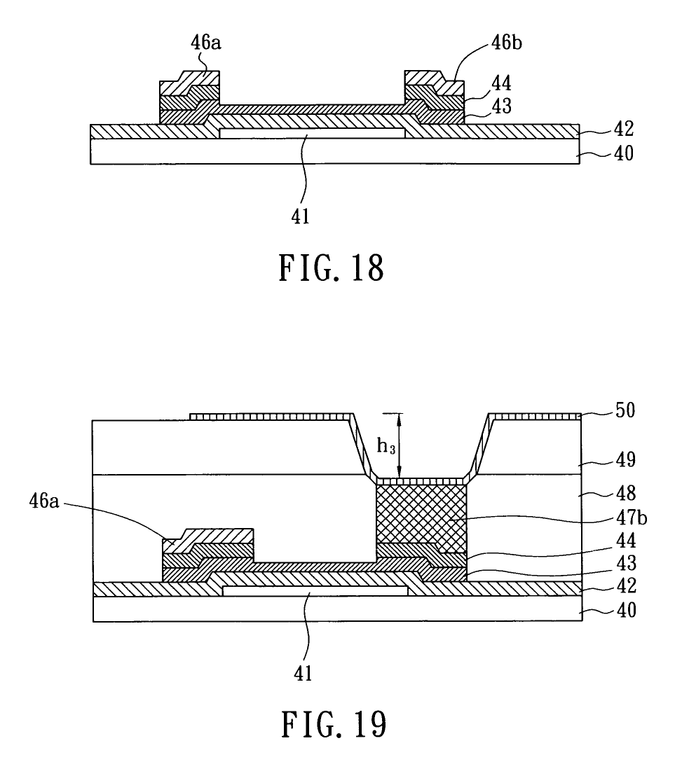

In FIG. 18, photo-lithography and etching are used again to formed a recessed portion at the center of the amorphous silicon layer 43.

Furthermore, a metal layer for the source/drain 46a, 46b is formed on two sides over the amorphous silicon layer 43, and the portion of the heavily doped amorphous silicon layer 44 uncovered by the source/drain 46a, 46b is then removed. The amorphous silicon layer 43 under the recessed portion is the channel region. A transistor is thus completed.

Then, similar to steps described in FIG. 8 to FIG. 13, a metal layer for the source/drain 47b, a color filter layer 48, a planarization layer 49 and a transparent conductive layer 50 can be formed. As shown in FIG. 19, the depth h3 of the transparent conductive layer 50 as well as the contact area is significantly reduced. Furthermore, the profile of the transparent conductive layer 50 is not overly abrupt so that the breaking or cracking of the portion of the pixel electrode can be prevented.

Afterwards, an organic light-emitting layer (not shown) and a cathode layer (not shown) are deposited so as to complete an active matrix organic light-emitting display (AMOLED).

In the present invention, an organic light-emitting device having a bottom-gate amorphous silicon TFT and an organic light-emitting device having a top-gate poly-silicon TFT are disclosed. However, the present invention is not limited the afore-mentioned embodiments. Even though an organic light-emitting device having a crystalline transistor is within the scope of the present invention.

According to the above discussion, it is apparent that the present invention discloses an organic light-emitting device with an integrated color filter and a method for manufacturing the same so as to reduce the contact resistance and prevent the breaking or cracking of the portion of a pixel electrode formed in the contact hole with only one additional photo-lithographic process. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. An organic light-emitting device, comprising:
a substrate;
a transistor formed on the substrate;
a source/drain metal layer coupled to the transistor;
a metal layer formed on the source/drain metal layer;
a color filter layer formed on the transistor and exposing the metal layer;
a planarization layer formed on the color filter layer and exposing the metal layer; and
a transparent conductive layer formed on the planarization layer and coupled to the metal layer.

2. The organic light-emitting device as recited in claim 1, wherein the transistor comprises:
a poly-silicon layer formed on the substrate and comprising a channel region and source/drain diffusion regions;
a gate insulating layer formed on the substrate and covering the poly-silicon layer;
a gate layer formed on the gate insulating layer;
an insulating layer formed on the gate layer and the gate insulating layer; and
contact holes penetrating the insulating layer and the gate insulating layer so as to expose the source/drain diffusion regions.

3. The organic light-emitting device as recited in claim 1, wherein the transistor comprises:
a gate layer formed on the substrate;
a gate insulating layer formed on the substrate and covering the gate layer;
an amorphous silicon layer formed on the gate insulating layer and comprising a channel region; and
a heavily doped amorphous silicon layer formed on two sides of the amorphous silicon layer.

4. The organic light-emitting device as recited in claim 1, wherein the metal layer and the source/drain metal layer are formed of the same material.

5. The organic light-emitting device as recited in claim 1, wherein the substrate is a glass substrate.

6. The organic light-emitting device as recited in claim 1, wherein the planarization layer is an organic material layer.

7. The organic light-emitting device as recited in claim 1, wherein the transparent conductive layer is an indium-tin oxide (ITO) layer.

8. The organic light-emitting device as recited in claim 2, wherein the gate insulating layer is a silicon oxide layer.

9. The organic light-emitting device as recited in claim 2, wherein the insulating layer is a silicon oxide layer.

10. The organic light-emitting device as recited in claim 3, wherein the gate insulating layer is a silicon oxide layer.

11. A method for manufacturing an organic light-emitting device, comprising steps of:
providing a substrate;
forming a transistor on the substrate;
forming a source/drain metal layer coupled to the transistor;
forming a metal layer on the source/drain metal layer;
forming a color filter layer on the transistor and the color filter layer exposing the metal layer;
forming a planarization layer on the color filter layer and the planarization layer exposing the metal layer; and
forming a transparent conductive layer on the planarization layer and the transparent conductive layer being coupled to the metal layer.

12. The method as recited in claim 11, wherein steps for manufacturing the transistor comprise:
forming a poly-silicon layer on the substrate;
forming a gate insulating layer on the substrate and the gate insulating layer covering the poly-silicon layer;
forming a gate layer on the gate insulating layer;
performing a ion-implantation process so as to form source/drain diffusion regions in the poly-silicon layer;
forming an insulating layer on the gate layer and the gate insulating layer; and
forming contact holes penetrating the insulating layer and the gate insulating layer so as to expose the source/drain diffusion regions.

13. The method as recited in claim 11, wherein steps for manufacturing the transistor comprise:
forming a gate layer on the substrate;
forming a gate insulating layer on the substrate and the gate insulating layer covering the gate layer;
forming an amorphous silicon layer on the gate insulating layer and the amorphous silicon layer comprising a channel region; and
forming a heavily doped amorphous silicon layer on two sides of the amorphous silicon layer.

14. The method as recited in claim 11, further comprising a step of:
forming a photo-resist layer on the metal layer.

15. The method as recited in claim 14, further comprising a step of:
performing a dry-etching process so as to remove the part of the metal layer uncovered by the photo-resist layer.

16. The method as recited in claim 15, further comprising a step of:
performing a lift-off process so as to remove the photo-resist layer.

17. The method as recited in claim 11, wherein the metal layer and the source/drain metal layer are formed of the same material.

18. The method as recited in claim 11, wherein the substrate is a glass substrate.

19. The method as recited in claim 11, wherein the planarization layer is an organic material layer.

20. The method as recited in claim 11, wherein the transparent conductive layer is an indium-tin oxide (ITO) layer.

21. The method as recited in claim 12, wherein the gate insulating layer is a silicon oxide layer.

22. The method as recited in claim 12, wherein the insulating layer is a silicon oxide layer.

23. The method as recited in claim 13, wherein the gate insulating layer is a silicon oxide layer.
